(19) United States
(12) Patent Application Publication
(10) Pub. No.: US 2024/0313180 A1
(43) Pub. Date: Sep. 19, 2024

(54) MICRO LIGHT-EMITTING DIODE PIXEL STRUCTURE AND METHOD FOR FORMING THE SAME

(71) Applicant: Lextar Electronics Corporation, Hsinchu (TW)

(72) Inventors: Shiou-Yi KUO, Hsinchu City (TW); Guo-Yi SHIU, Hsinchu City (TW)

(21) Appl. No.: 18/498,743

(22) Filed: Oct. 31, 2023

(30) Foreign Application Priority Data
Mar. 17, 2023 (TW) 112109939

(51) Int. Cl. H01L 33/62; H01L 25/075; H01L 33/24

(52) U.S. Cl. CPC H01L 33/62; H01L 25/0753; H01L 33/24; H01L 2933/0066

(57) ABSTRACT

A micro light-emitting diode pixel structure and a method for forming the same are provided. The micro light emitting diode pixel structure includes micro light emitting diode chips, redistribution layers, bonding pads, an insulating layer, a flexible material layer and a first hard mask pattern. The redistribution layers are electrically connected to electrode surfaces of the micro light-emitting diode chips. The bonding pads are disposed under the redistribution layers. The insulation layer is disposed between the redistribution layers and the bonding pads. The flexible material layer disposed on the insulating layer to cover the micro light-emitting diode chips, the redistribution layers and insulation layer. The first hard mask pattern is disposed under or above the flexible material layers. In a cross-sectional view, the first hard mask pattern has a first edge and the flexible material layer has a second edge flush with the first edge.

### CROSS REFERENCE TO RELATED APPLICATIONS

This application claims priority of Taiwan Patent Application No. 112109939, filed on Mar. 17, 2023, and the content of which is incorporated by reference herein in its entireties.

### BACKGROUND OF THE DISCLOSURE

### Field of the Disclosure

The present disclosure relates to a micro light-emitting diode pixel structure and a method for forming the same, and, in particular, to a micro light-emitting diode pixel structure having high cutting efficiency and a method for forming the same.

### Description of the Related Art

Since light-emitting diodes (LEDs) have the advantage of low power consumption, light-emitting diode displays have become the mainstream in the field of display technology. However, during the manufacturing process of light-emitting diode displays, the size of the pixel structure composed of red, green and blue (three primary colors) light-emitting diodes cannot be further reduced due to the fixed thickness and size of the light-emitting diodes. Therefore, it is difficult for the current pixel structure of the light-emitting diode to achieve the goals of small spacing, large light-emitting area, high process yield and low cost.

### BRIEF SUMMARY OF THE DISCLOSURE

An embodiment of the present disclosure provides a micro light-emitting diode pixel device structure. The micro light-emitting diode pixel structure includes micro light-emitting diode chips, redistribution layers, bonding pads, an insulating layer, a flexible material layer and a first hard mask pattern. The micro light-emitting diode chips are arranged side by side. Each of the micro-light-emitting diode chips includes an electrode surface and a light-emitting surface. The redistribution layers are arranged at the electrode surfaces of the micro light-emitting diode chips and electrically connected to the micro light-emitting diode chips respectively. The bonding pads are disposed under the redistribution layers. The insulation layer is disposed between the redistribution layers and the bonding pads. The redistribution layers pass through the insulating layer to electrically connect to the bonding pads. The flexible material layer disposed on the insulating layer to covers the light-emitting surfaces of the micro light-emitting diode chips, the redistribution layers, and the insulating layer. The first hard mask pattern is disposed under or above the flexible material layer. In a cross-sectional view, the first hard mask pattern has a first edge and the flexible material layer has a second edge, and the first edge is flush with the second edge.

In addition, an embodiment of the present disclosure provides a method for forming a micro light-emitting diode pixel device structure. The method for forming the micro light-emitting diode pixel structure includes providing a first carrier. The method further includes forming a first adhesive layer on a surface of the first carrier. The method further includes forming a first hard mask pattern on the first adhesive layer. The first hard mask pattern has openings to expose the first adhesive layer. The method further includes forming bonding pads on the first hard mask pattern. The bonding pads are in contact with the first adhesive layer through the openings. The method further includes forming an insulating layer on the first hard mask pattern and the bonding pads. The insulating layer has via holes to expose the bonding pads. The method further includes forming redistribution layers on the insulating layer. The redistribution layers are electrically connected to the bonding pads through the via holes. The method further includes providing micro light-emitting diode chips on the first carrier. The micro light-emitting diode chips are electrically connected to the redistribution layers. The method further includes forming a flexible material layer on the first carrier to cover the micro light-emitting diode chips, the redistribution layers, and the insulating layer. The method further includes attaching a second carrier to the flexible material layer. The second carrier has a second adhesive layer, and the flexible material layer is in contact with the second adhesive layer. The method further includes removing the first carrier and the first adhesive layer. The method further includes performing an anisotropic etching process to remove a portion of the flexible material layer at the periphery which is not overlapped with the first hard mask pattern in a vertical direction. After performing the anisotropic etching process, in a cross-sectional view, the first hard mask pattern has a first edge and the flexible material layer has a second edge, and the first edge is flush with the second edge. The method further includes removing the second carrier and the second adhesive layer.

Moreover, an embodiment of the present disclosure provides a method for forming a micro light-emitting diode pixel structure. The method for forming the micro light-emitting diode pixel structure includes providing a carrier. The method further includes forming an adhesive layer on a surface of the carrier. The method further includes forming bonding pads on the adhesive layer. The method further includes forming an insulating layer on the adhesive layer and the bonding pads. The insulation layer has via holes to expose the bonding pads. The method further includes forming redistribution layers on the insulating layer. The redistribution layers are electrically connected to the bonding pads through the via holes. The method further includes providing micro light-emitting diode chips on the carrier. The micro light-emitting diode chips are electrically connected to the redistribution layers. The method further includes forming a flexible material layer on the carrier to cover the micro light-emitting diode chips, the redistribution layers, and the insulating layer. The method further includes forming a hard mask pattern on the flexible material layer. The method further includes performing an anisotropic etching process to remove a portion of the flexible material layer at the periphery which is not overlapped with the hard mask pattern in a vertical direction. After performing the anisotropic etching process, in a cross-sectional view, the hard mask pattern has a first edge and the flexible material layer has a second edge, and the first edge is flush with the second edge. The method further includes removing the carrier and the adhesive layer

### BRIEF DESCRIPTION OF THE DRAWINGS

The present disclosure can be more fully understood by reading the subsequent detailed description and examples with references made to the accompanying drawings, wherein:

FIG. 1 is a schematic top view of a micro light-emitting diode pixel structure in accordance with some embodiments of the disclosure;

FIGS. 2A, 2B, and 2C are schematic cross-sectional views along the line A-A′ of the micro light-emitting diode pixel structure in accordance with some embodiments of the disclosure shown in FIG. 1;

FIG. 3 is a schematic top view of the micro light-emitting diode pixel structure in accordance with some embodiments of the disclosure;

FIG. 4 is an equivalent circuit diagram of the micro light-emitting diode pixel structure in accordance with some embodiments of the disclosure shown in FIG. 3;

FIGS. 5A, 5B, and 5C are schematic cross-sectional views along the line A-A′ of the micro light-emitting diode pixel structure in accordance with some embodiments of the disclosure shown in FIG. 3;

FIGS. 6A, 6B, 6C, 6D, 6E, 6F, 6G, 6H, 6I and 6J are schematic cross-sectional views at different stages of forming the micro light-emitting diode pixel structure in accordance with some embodiments of the disclosure as shown in FIG. 2A;

FIGS. 7A, 7B, 7C and 7D are schematic cross-sectional views at different stages of forming the micro light-emitting diode pixel structure in accordance with some embodiments of the disclosure as shown in FIG. 2B;

FIGS. 8A, 8B and 8C are schematic cross-sectional views at different stages of forming the micro light-emitting diode pixel structure in accordance with some embodiments of the disclosure as shown in FIG. 2B; and

FIGS. 9A, 9B, 9C, 9D, 9E, 9F and 9G are schematic cross-sectional views at different stages of forming the micro light-emitting diode pixel structure in accordance with some embodiments of the disclosure as shown in FIG. 2C.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

The embodiments of the present disclosure are described fully hereinafter with reference to the accompanying drawings, and the advantages and features of the present disclosure and methods of achieving them will be apparent from the following exemplary embodiments that will be described in more detail with reference to the accompanying drawings. It should be noted, however, that the present disclosure is not limited to the following exemplary embodiments, and may be implemented in various forms. Accordingly, the exemplary embodiments are provided only to disclose the present disclosure and let those skilled in the art know the category of the present disclosure. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure. The micro light-emitting diode pixel structure provided in some embodiments of the present disclosure includes a hard mask pattern disposed under or above a flexible material layer, and is fabricated by an anisotropic etching process to improve the precision and accuracy of the dicing process and the flatness of the sidewall profile of the micro light-emitting diode pixel structure after performing the dicing process. Therefore, the process yield of the micro light-emitting diode pixel structure is further improved. Because the dicing loss is reduced, the yield of the micro light-emitting diode pixel structure is increased.

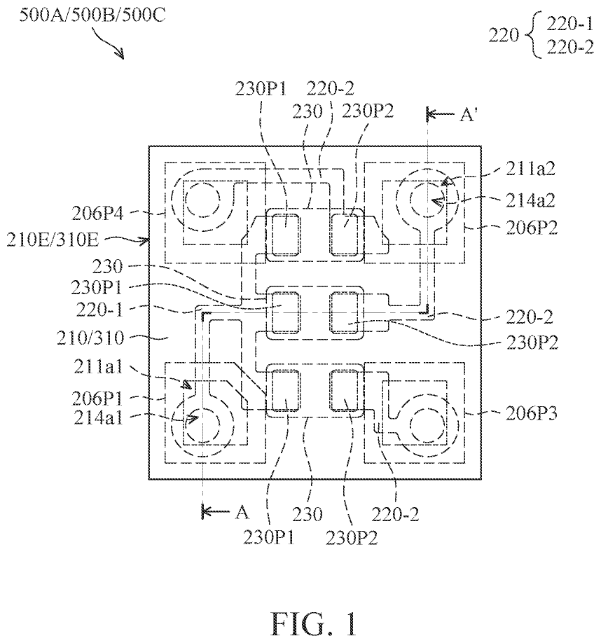

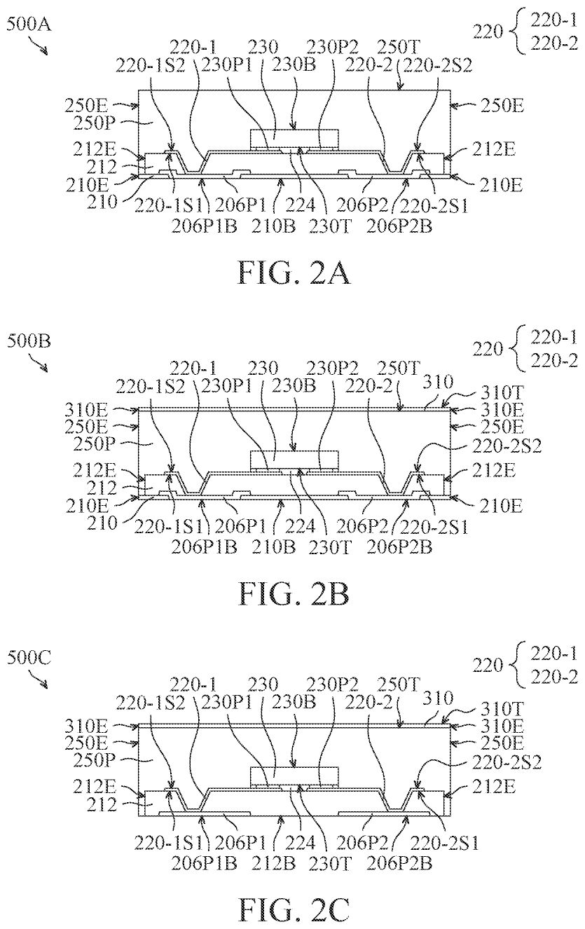

FIG. 1 is a schematic top view of micro light-emitting diode pixel structures 500A, 500B, or 500C in accordance with some embodiments of the disclosure. FIG. 2A is a schematic cross-sectional view along the line A-A′ of the micro light-emitting diode pixel structure 500A in accordance with some embodiments of the disclosure shown in FIG. 1. The micro light-emitting diode pixel structure 500A includes micro light-emitting diode chips 230 (including electrodes 230P1 and 230P2), a redistribution layer 220, a flexible material layer 250P, a first hard mask pattern 210, an insulating layer 212 and bonding pads 206P1, 206P2, 206P3, and 206P4. For illustration, FIG. 1 only shows the micro light-emitting diode chip 230, the electrodes 230P1 and 230P2, the bonding pads 206P1, 206P2, 206P3 and 206P4, the redistribution layer 220 and the first hard mask pattern 210. The flexible material layer 250P, the insulating layer 212 and other features can be seen in the schematic cross-sectional view of FIG. 2A.

As shown in FIG. 1 and FIG. 2A, the micro light-emitting diode chips 230 are arranged side by side on the insulating layer 212, and each of the micro light-emitting diode chips 230 includes an electrode surface 230T and a light-emitting surface 230B opposite to each other. Each of the micro light-emitting diode chips 230 includes the electrodes 230P1 and 230P2 disposed at the electrode surface 230T. In some embodiments, the electrodes 230P1 and 230P2 have different or opposite polarities. For example, the electrode 230P1 is a cathode, and the electrode 230P2 is an anode. In some embodiments, the micro light-emitting diode chips 230 respectively emit lights of different wavelengths to form a pixel unit. For example, the micro light-emitting diode chips 230 emitting lights of different colors may include the micro light-emitting diode chip emitting red light, the micro light-emitting diode chip emitting green light, and the micro light-emitting diode chip emitting blue light. However, embodiments of the disclosure are not limited thereto. In some embodiments, the micro light-emitting diode chips 230 include the micro light-emitting diode chips that emit light of the same wavelength, such as blue light or ultraviolet (UV) light, and are respectively coated with phosphors or quantum dot materials in different compositions to absorb the light emitted from the micro light-emitting diode chips and convert them into red light, green light or blue light, to form a pixel unit. In some embodiments, the light-emitting surface 230B of the micro light-emitting diode chip 230 may be a rough surface, so as to increase the luminous efficiency of the micro light-emitting diode pixel structure 500A. In some embodiments, the electrodes 230P1 and 230P2 include a conductive material such as chromium (Cr), aluminum (Al), nickel (Ni), gold (Au), platinum (Pt), tin (Sn), copper (Cu), or combinations thereof. In addition, the electrodes 230P1 and 230P2 can be formed by a plating process, such as evaporation or electroplating and a subsequent patterning process.

The redistribution layer 220 is disposed at the electrode surface 230T of each of the micro light-emitting diode chips 230 and is electrically connected to the corresponding micro light-emitting diode chip 230. In some embodiments, the redistribution layer 220 electrically connected to the corresponding micro light-emitting diode chip 230 includes redistribution layers 220-1 and 220-2. Specifically, the redistribution layer 220-1 has a first side 220-1S1 and a second side 220-1S2 opposite to each other; the redistribution layer 220-2 has a first side 220-2S1 and a second side 220-2S2 opposite to each other; the second side 220-1S2 of the redistribution layer 220-1 is in contact with the electrode 230P1 of the corresponding micro light-emitting diode chip 230, and the second side 220-2S2 of the redistribution layer 220-2 is in contact with the electrode 230P2 of the corresponding micro light-emitting diode chip 230. The redistribution layer 220 is used as the interconnection structure of the micro light-emitting diode pixel structure 500A to reroute (e.g. fan out) the electrical contact position from the original positions of the electrical nodes of the micro light-emitting diode chip 230 to the designated positions of the micro light-emitting diode pixel structure 500A. In some embodiments, the redistribution layer 220 includes a stack of conductive materials layers formed of, for example, chromium (Cr), aluminum (Al), nickel (Ni), gold (Au), platinum (Pt), tin (Sn), indium (In), copper (Cu), nickel-cobalt-aluminum (NCA), anisotropic conductive film (ACF) or a combination thereof. In addition, the redistribution layer 220 may be formed by a plating process, such as evaporation or electroplating.

In addition to the redistribution layer 220, the interconnect structure of the micro light-emitting diode pixel structure 500A further includes an insulating layer 212 and bonding pads 206P1, 206P2, 206P3 and 206P4. As shown in FIG. 2A, the insulating layer 212 is disposed under the redistribution layer 220-1 and 220-2 to face the first sides 220-1S1 and 220-2S1 of the redistribution layers 220-1 and 220-2. The bonding pads 206P1, 206P2, 206P3 and 206P4 are disposed under the insulating layer 212 and electrically connected to the redistribution layer 220-1 and 220-2 passing through the insulating layer 212 respectively. The bonding pads 206P1, 206P2, 206P3 and 206P4 can electrically connect to an external circuit (not shown). For example, in the embodiment shown in FIG. 1, the bonding pads 206P1, 206P2, 206P3 and 206P4 are located at the lower left corner, the upper right corner, the lower right corner and the upper left corner of the micro light-emitting diode pixel structure 500A respectively; the bonding pad 206P1 is electrically connected to three micro light-emitting diode chips 230, and the bonding pads 206P2, 206P3 and 206P4 are electrically connected to the corresponding one of the three micro light-emitting diode chips 230 respectively. Specifically, the electrodes 230P1 (such as the cathodes) of the three micro light-emitting diode chips 230 are electrically connected to the bonding pad 206P1 by one redistribution layer 220-1, and the electrodes 230P2 (such as the anodes) of the three micro light-emitting diode chips 230 are electrically connected respectively to the corresponding bonding pads 206P2, 206P3 and 206P4 by three different redistribution layers 220-2. That is, the micro light-emitting diode chips 230 of the micro light-emitting diode pixel structure 500A are electrically connected to each other by three anodes and one common-cathode. In other embodiments, the micro light-emitting diode chips 230 of the micro light-emitting diode pixel structure 500A are electrically connected to each other by three cathodes and one common-anode. In some embodiments, a distributed Bragg reflector (DBR) layer can be disposed on the redistribution layer 220 and the insulating layer 212 to increase the luminous efficiency of the micro light-emitting diode pixel structure 500A. In some embodiments, the insulating layer 212 includes polyimide (PI), epoxy resin (epoxy), benzocyclobutene (BCB) and other insulating materials with low dielectric constant and good step coverage, and can be formed by a coating process, for example, spin coating or spray coating. In some embodiments, the bonding pads 206P1, 206P2, 206P3 and 206P4 and the redistribution layers 220-1 and 220-2 may have the same or similar materials and formation processes.

As shown in FIG. 2A, the flexible material layer 250P covers and is in contact with the light-emitting surface 230B of the micro light-emitting diode chip 230 and the second sides 220-1S2 and 220-2S2 of the redistribution layers 220-1 and 220-2. In addition, the flexible material layer 250P may surround the micro light-emitting diode chip 230 and the insulating layer 212. In some embodiments, the flexible material layer 250P includes a flexible material with good light transmittance (for example, the light transmittance is greater than 90%), such as polymethyl methacrylate (PMMA), polyethylene terephthalate (PET), polyethylene naphthalate (PEN), polystyrene (PS), polypropylene (PP), polyamide (PA), polycarbonate (PC), polyimide (PI), epoxy, silicone, polydimethylsiloxane (PDMS) or a combination of any two or more of the above materials, and can be formed by, for example, film pasting, spray coating, or molding.

As shown in FIG. 2A, the micro light-emitting diode pixel structure 500A further includes an insulating layer 224 disposed between the micro light-emitting diode chip 230 and the insulating layer 212. Specifically, the insulating layer 224 is disposed under the electrode surface 230T of the micro light-emitting diode chip 230 and covers a portion of the surface of the insulating layer 212 right below the electrode surface 230T of the micro light-emitting diode chip 230. In addition, the insulating layer 224 further covers a portion of the second sides 220-1S2 and 220-2S2 of the redistribution layers 220-1 and 220-2 right below the electrode surface 230T. The insulating layer 224 is in contact with the redistribution layer 220 and the flexible material layer 250P. Moreover, the insulating layer 224 may surround the electrodes 230P1 and 230P2 of the micro light-emitting diode chip 230 to provide electrical insulation between the electrodes 230P1 and 230P2. In some embodiments, the insulating layers 212 and 224 may have the same or similar materials and formation processes.

The first hard mask pattern 210 is disposed under the insulating layer 212 so that the insulating layer 212 is disposed between the redistribution layer 220 and the first hard mask pattern 210. In the cross-sectional view shown in FIG. 2A, an edge 210E of the first hard mask pattern 210 is flush with an edge 250E of the flexible material layer 250P, and an edge 212E of the insulating layer 212 is located closer to the micro light-emitting diode chip 230 than the edge 210E of the first hard mask pattern 210. That is, a part of the first hard mask pattern 210 around the edge 210E is not covered by the insulating layer 212 so that the flexible material layer 250P surrounds the insulating layer 212 and is in contact with the first hard mask pattern 210. Moreover, the first hard mask pattern 210 may surround the bonding pads 206P1 and 206P2. In this embodiment, the first hard mask pattern 210 is the bottommost layer of the micro light-emitting diode pixel structure 500A, and the flexible material layer 250P is the topmost layer of the micro light-emitting diode pixel structure 500A. As shown in FIG. 2A, the first hard mask pattern 210 has a bottom surface 210B away from the flexible material layer 250P. The bonding pads 206P1 and 206P2 respectively have bottom surfaces 206P1B and 206P2B away from the redistribution layer 220. The bottom surface 210B of the first hard mask pattern 210 and the bottom surfaces 206P1B, 206P2B of the bonding pads 206P1, 206P2 are flush with each other and collectively form the bottom surface of the micro light-emitting diode pixel structure 500A. Moreover, the top surface 250T of the flexible material layer 250P forms the top surface of the micro light-emitting diode pixel structure 500A.

The first hard mask pattern 210 may serve as a mask during the dicing process (e.g., the anisotropic etching process such as plasma dicing) for forming the micro light-emitting diode pixel structure 500A, so as to improve the dicing efficiency of the dicing process of the micro light-emitting diode pixel structure. In some embodiments, the first hard mask pattern 210 includes a material with good light transmittance, and the material of the first hard mask pattern 210 is different from that of the insulating layer 212. For example, when the insulating layer 212 includes polyimide (PI), epoxy, and/or benzocyclobutene (BCB), the first hard mask pattern 210 may include silicon dioxide (SiO₂). In addition, in some embodiments, the etching selectivity ratio of the first hard mask pattern 210 to the flexible material layer 250P is between 1:10 and 1:1000. Furthermore, the etching selectivity ratio of the bonding pads 206P1 and 206P2 to the flexible material layer 250P may be between 1:10 and 1:200. In the dicing process of forming the micro light-emitting diode pixel structure 500A, due to the high etching selectivity between the first hard mask pattern 210 and the flexible material layer 250P, the geometric shape and dimensions of the micro light-emitting diode pixel structure 500A in the top view can be formed by using the first hard mask pattern 210 (and the bonding pads 206P1 and 206P2) as a mask. In some embodiments, the top view shape of the first hard mask pattern 210, such as polygon, circle, ellipse or other geometric shapes, is determined according to the predetermined geometry of the micro light-emitting diode pixel structure. In addition, the edge of the micro light-emitting diode pixel structure (composed of the edge 250E of the flexible material layer 250P and the edge 210E of the first hard mask pattern 210) can be etched to have a concave-convex profile by the design of the first hard mask pattern 210. In some embodiment, the contour line of the micro light-emitting diode pixel structure in the top view may have a concave-convex shape, for example, stamp, wavy or jagged shape. In some embodiments, the first hard mask pattern 210 is formed using a deposition process such as plasma enhanced chemical vapor deposition (PECVD) and a subsequent patterning process.

FIG. 2B is a schematic cross-sectional view along the line A-A′ of the micro light-emitting diode pixel structure 500B in accordance with some embodiments of the disclosure shown in FIG. 1, and the reference numbers the same or similar as those previously described with reference to FIGS. 1 and 2A denote the same or similar elements. In some embodiments, the hard mask patterns used to form the geometric shape and dimensions of the micro light-emitting diode pixel structure are provided on both the top side and bottom side of the micro light-emitting diode pixel structure. As shown in FIG. 2B, the difference between the micro light-emitting diode pixel structure 500B and the micro light-emitting diode pixel structure 500A is that the micro light-emitting diode pixel structure 500B further includes a second hard mask pattern 310 disposed over the flexible material layer 250P, so that the second hard mask pattern 310 is arranged as the topmost layer of the micro light-emitting diode pixel structure 500B. In addition, the first hard mask pattern 210 and the bonding pads 206P1 and 206P2 are arranged as the bottommost layer of the micro light-emitting diode pixel structure 500B. As shown in FIG. 2B, the flexible material layer 250P has the top surface 250T away from the first hard mask pattern 210, and the second hard mask pattern 310 covers and is in contact with the top surface 250T of the flexible material layer 250P, so that the top surface 310T of the second hard mask pattern 310 constitutes the top surface of the micro light-emitting diode pixel structure 500B. Moreover, the bottom surface 210B of the first hard mask pattern 210 and the bottom surfaces 206P1B and 206P2B of the bonding pads 206P1 and 206P2 are flush with each other and collectively form the bottom surface of the micro light-emitting diode pixel structure 500B. As shown in FIG. 2B, the edge 210E of the first hard mask pattern 210 may be flush with the edge 310E of the second hard mask pattern 310 and the edge 250E of the flexible material layer 250P. In some embodiments, the first hard mask pattern 210 and the second hard mask pattern 310 in the micro light-emitting diode pixel structure 500B may have the same or similar material, fabrication process and top-view shape.

FIG. 2C is a schematic cross-sectional view along the line A-A′ of the micro light-emitting diode pixel structure 500C in accordance with some embodiments of the disclosure shown in FIG. 1, and the reference numbers the same or similar as those previously described with reference to FIGS. 1, 2A and 2B denote the same or similar element. In some embodiments, the hard mask pattern used to form the geometric shape and dimensions of the micro light-emitting diode pixel structure is provided on the top side of the micro light-emitting diode pixel structure. In this embodiment, since only the second hard mask pattern 310 is provided, the marks of the first hard mask pattern 210 and the openings 211al and 211a2 of the first hard mask pattern 210 denoted in FIG. 1 can be omitted. As shown in FIG. 2C, the difference between the micro light-emitting diode pixel structure 500C and the micro light-emitting diode pixel structure 500A is that the micro light-emitting diode pixel structure 500C includes a second hard mask pattern 310 disposed on the flexible material layer 250P so that the second hard mask pattern 310 is the topmost layer of the micro light-emitting diode pixel structure 500C. In other words, the top surface 310T of the second hard mask pattern 310 may constitute the top surface of the micro light-emitting diode pixel structure 500C. In addition, the insulating layer 212 may have the bottom surface 212B away from the micro light-emitting diode chip 230. The bottom surface 212B is flush with the bottom surfaces 206P1B and 206P2B of the bonding pads 206P1 and 206P2 and collectively form the bottom surface of the micro light-emitting diode pixel structure 500C. Also, the edge 310E of the second hard mask pattern 310 is flush with the edge 250E of the flexible material layer 250P.

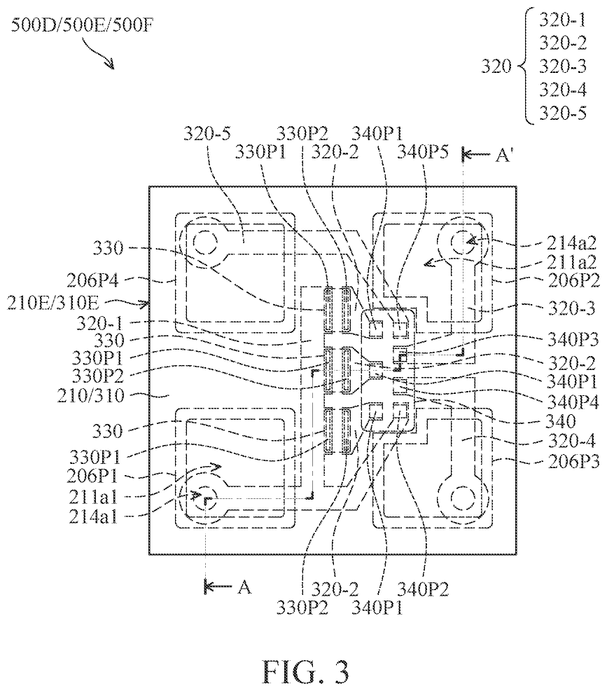

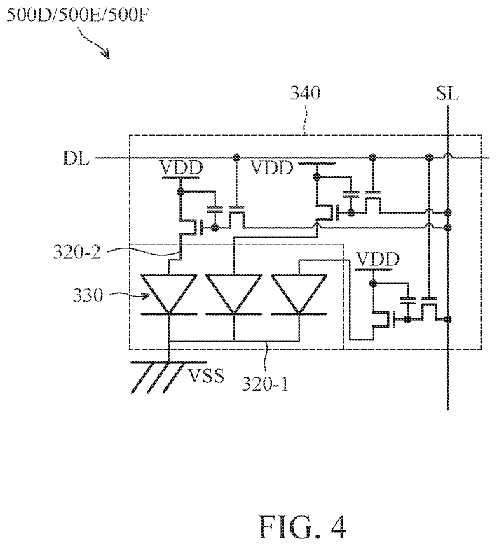

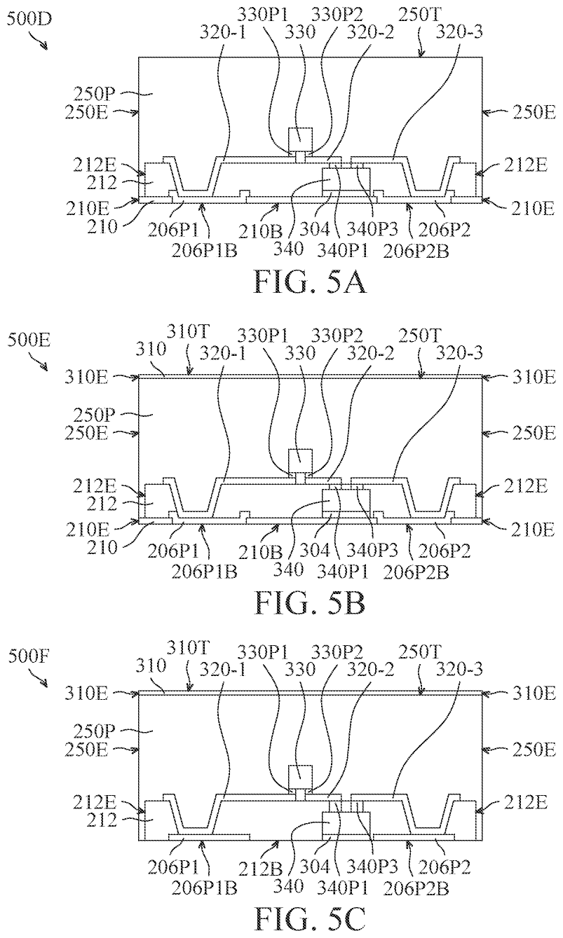

FIG. 3 is a schematic top view of micro light-emitting diode pixel structures in accordance with some embodiments of the disclosure, which includes micro light-emitting diode pixel structures 500D, 500E, and 500F. Similar to FIG. 1, since there are no openings of the hard mask pattern in some embodiments (e.g. the micro light-emitting diode pixel structure 500F), the marks of the openings (e.g. 211al and 211a2) denoted in FIG. 3 can be omitted when the aforementioned embodiments are considered. FIG. 4 is an equivalent circuit diagram of the micro light-emitting diode pixel structures 500D, 500E, and 500F in accordance with some embodiments of the disclosure shown in FIG. 3. FIGS. 5A, 5B, and 5C are schematic cross-sectional views along the line A-A′ of the micro light-emitting diode pixel structures 500D, 500E, and 500F in accordance with some embodiments of the disclosure shown in FIG. 3, and the reference numbers the same or similar as those previously described with reference to FIGS. 1, 2A, 2B and 2C denote the same or similar element. The micro light-emitting diode pixel structures 500D, 500E, and 500F may integrate a control device and micro light-emitting diodes into a pixel package so that the micro light-emitting diodes can be individually/independently controlled. The difference between the micro light-emitting diode pixel structures 500D, 500E, and 500F shown in FIGS. 5A, 5B, and 5C and the micro light-emitting diode pixel structures 500A, 500B, and 500C shown in FIGS. 2A, 2B, and 2C is that the micro light-emitting diode pixel structures 500D, 500E, and 500F include micro light-emitting diode chips 330, a control device 340, and redistribution layers 320 (including redistribution layers 320-1, 320-2, 320-3, 320-4 and 320-5).

As shown in FIGS. 3, each of the micro light-emitting diode chips 330 includes electrodes 330P1 and 330P2. In some embodiments, the micro light-emitting diode chips 330 may include the same or similar structures to the micro light-emitting diode chips 230, and the dimensions of the micro light-emitting diode chips 330 may be the same or different to those of the micro light-emitting diode chips 220. For example, the micro light-emitting diode chips 230 and 330 may have the same structure. In addition, the dimension of the micro light-emitting diode chip 330 may be smaller than that of the micro light-emitting diode chip 230.

As shown in FIGS. 5A, 5B, and 5C, the control device 340 is disposed between the micro light-emitting diode chip 330 and the bonding pads 206P1 and 206P2. In addition, the control device 340 may be fixed on the first hard mask pattern 210 by an adhesive layer 304. The control device 340 is electrically connected to the micro light-emitting diode chip 330 for driving the micro light-emitting diode chip 330 to emit light. In some embodiments, the control device 340 includes a 2TIC circuit composed of two thin film transistors (TFT, T) and one capacitor(C). As shown in FIG. 4, the 2TIC circuit is electrically connected between a power supply terminal VDD and a ground terminal VSS, and controlled by a select line SL and a data line DL which may control the input of the scanning voltage signal and the data voltage signal. Therefore, the control device 340 may control the light emission of the micro light-emitting diode chip 330.

In some embodiments, the control device 340 includes contact pads, such as contact pads 340P1, 340P2, 340P3, 340P4 and 340P5. The contact pad 340P1 of the control device 340 may be electrically connected to the corresponding electrode 330P2 of the micro light-emitting diode chip 330. Moreover, the contact pads 340P2, 340P3, 340P4, and 340P5 of the control device 340 may be electrically connected to the ground terminal VSS, the power supply terminal VDD, the data voltage signal source, and the scanning voltage signal source of the external circuit, respectively.

As shown in FIG. 3, in some embodiments, the electrode 330P1 (cathode) of each of the micro light-emitting diode chips 330 and the contact pad 340P2 of the control device 340 may be electrically connected to the bonding pad 206P1 by the redistribution layer 320-1, and further electrically connected to the ground terminal VSS of the external circuit by the bonding pad 206P1. The electrode 330P2 (anode) of each of the micro light-emitting diode chips 330 may be electrically connected individually to the corresponding contact pad 340P1 of the control device 340 by the redistribution layer 320-2, so that the control device 340 may electrically control the micro light-emitting diode chips 330. The control device 340 may be further electrically connected to the bonding pad 206P2 by the redistribution layer 320-3. Specifically, the contact pad 340P3 of the control device 340 may be electrically connected to the bonding pad 206P2 by the redistribution layer 320-3 and further electrically connected to the power supply terminal VDD of the external circuit by the bonding pad 206P2. The contact pad 340P4 of the control device 340 may be electrically connected to the bonding pad 206P3 by the redistribution layer 320-4, and further electrically connected to the data voltage signal source of the external circuit by the bonding pad 206P3. The contact pad 340P5 of the control device 340 may be electrically connected to the bonding pad 206P4 by the redistribution layer 320-5, and further electrically connected to the scanning voltage signal source of the external circuit by the bonding pad 206P4.

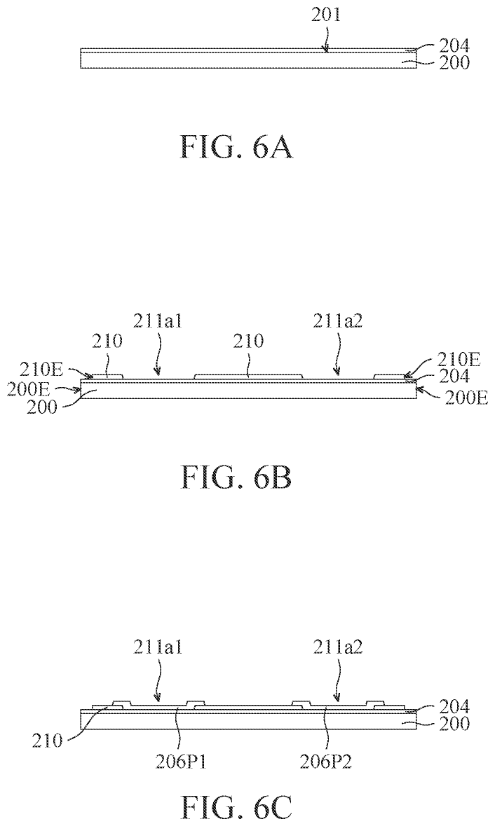

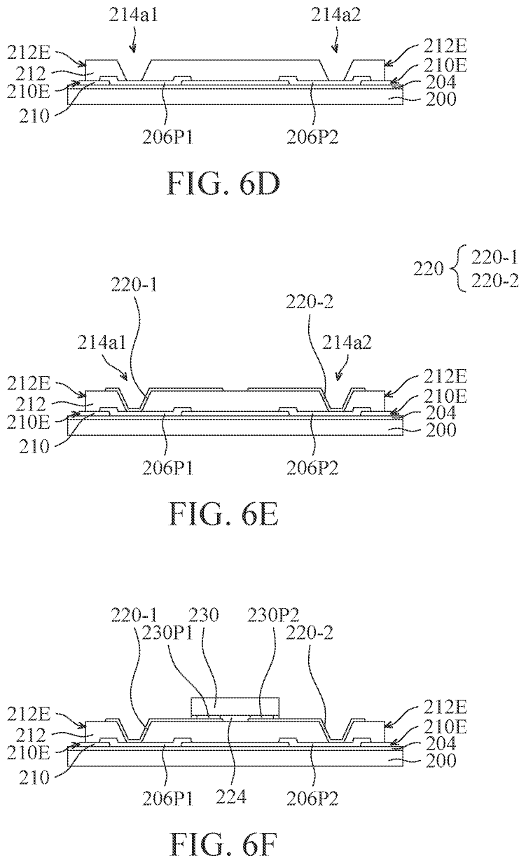

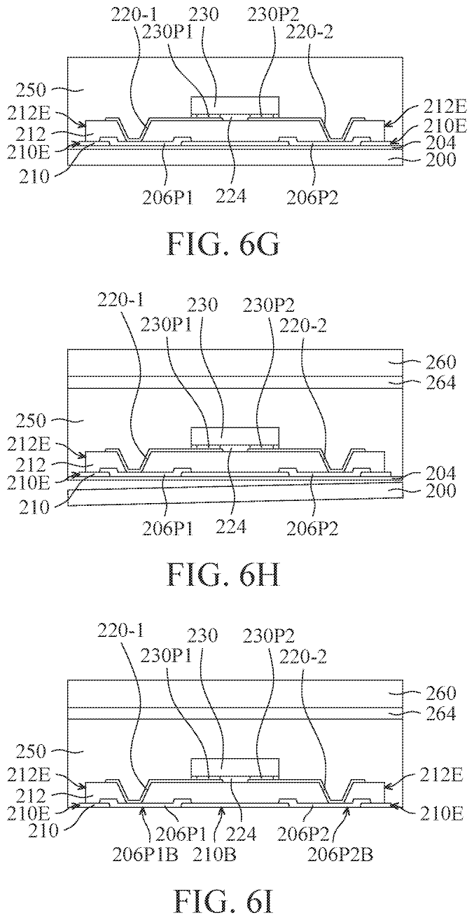

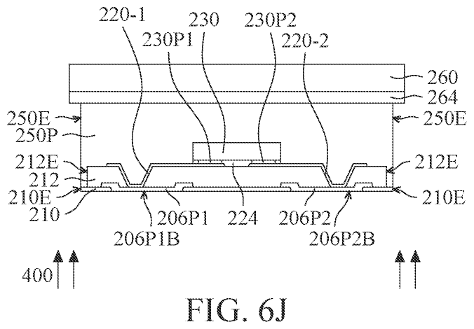

The method for forming the micro light-emitting diode pixel structure is described below. FIGS. 6A-6J, 7A-7D, 8A-8C, and 9A-9G illustrate methods for forming a micro light-emitting diode pixel structure (single pixel unit) for the sake of the convenience, though the embodiments of the present disclosure are not limited thereto. In some other embodiments, the methods for forming the micro light-emitting diode pixel structure may form periodically arranged micro light-emitting diode pixel structures.

FIGS. 6A, 6B, 6C, 6D, 6E, 6F, 6G, 6H, 6I and 6J are schematic cross-sectional views at different stages of forming the micro light-emitting diode pixel structure 500A in accordance with some embodiments of the disclosure as shown in FIG. 2A. As shown in FIG. 6A, first, a first carrier 200 is provided. The first carrier 200 is used to carry the micro light-emitting diode chips subsequently transferred onto a surface 201 of the first carrier 200. In some embodiments, the material of the first carrier 200 includes glass, sapphire, transparent polymer or a combination thereof. Next, the adhesive layer 204 is formed, by coating for example, on the surface 201 of the first carrier 200. In some embodiments, the adhesive layer 204 includes polymer materials having adhesive force and easily to be dissociated and destroyed at the interface with the first carrier 200 in the subsequent removal process (such as laser lift-off (LLO)), for example, polyimide (PI), epoxy, or silicone.

Next, as shown in FIG. 6B, a deposition process and a subsequent patterning process are performed to form the first hard mask pattern 210 on the first carrier 200. The first hard mask pattern 210 has openings 211al and 211a2 to expose the adhesive layer 204. In some embodiments, the edge 210E of the first hard mask pattern 210 may be located inward relatively to the edge 200E of the first carrier 200. In other words, the edge 210E of the first hard mask pattern 210 may be closer to the center of the first carrier 200 than the edge 200E of the first carrier 200, therefore a portion of the first carrier 200, e.g. around the edge 200E, is not covered by the first hard mask pattern 210.

Next, as shown in FIG. 6C, a plating process and a subsequent patterning process are performed to form the bonding pads 206P1 and 206P2 on the first carrier 200. The bonding pads 206P1 and 206P2 are surrounded by the first hard mask pattern 210. The bonding pads 206P1 and 206P2 are in contact with the adhesive layer 204 through the openings 211al and 211a2 of the first hard mask pattern 210. In other words, the bonding pads 206P1 and 206P2 are attached to the first carrier 200 by the adhesive layer 204.

In some embodiments, the sequence of the process shown in FIG. 6B and FIG. 6C can be changed. That is, after coating the adhesive layer 204, the bonding pads 206P1 and 206P2 are formed on the adhesive layer 204, and then the first hard mask pattern 210 is formed on the adhesive layer 204 and the bonding pads 206P1 and 206P2. The first hard mask pattern 210 has openings 211al and 211a2 to respectively expose the bonding pads 206P1 and 206P2.

Next, as shown in FIG. 6D, a coating process and a subsequent patterning process are performed to form the insulating layer 212 on the first hard mask pattern 210 and the bonding pads 206P1 and 206P2. The insulation layer 212 has via holes 214a1 and 214a2 to expose the bonding pads 206P1 and 206P2. In some embodiments, the edge 212E of the insulating layer 212 may be located inward relatively to the edge 210E of the first hard mask pattern 210. In other words, the edge 212E of the insulating layer 212 may be closer to the center of the first carrier 200 than the edge 210E of the first hard mask pattern 210, therefore a portion of the first hard mask pattern 210, e.g. around the edge 210E, is not covered by the insulating layer 212. Alternatively, in some embodiments, the edge 212E of the insulating layer 212 may be not located inward relatively to the edge 210E of the first hard mask pattern 210, and may be connected with the insulating layer 212 of the intermediate structure of the adjacent micro light-emitting diode pixel structure.

Next, as shown in FIG. 6E, a plating process and a subsequent patterning process are performed to form the redistribution layers 220-1 and 220-2 on the insulating layer 212. The redistribution layers 220-1 and 220-2 cover a portion of the insulation layer 212. Moreover, the redistribution layers 220-1 and 220-2 are electrically connected to the corresponding bonding pads 206P1 and 206P2 through the via holes 214a1 and 214a2.

Next, as shown in FIG. 6F, the micro light-emitting diode chip 230 may be transferred onto the first carrier 200 by transfer processes such as stamp transferring and/or laser transferring. The electrodes 230P1 and 230P2 of the micro light-emitting diode chip 230 are electrically connected to the redistribution layers 220-1 and 220-2. Furthermore, the insulating layer 224 is filled in the gap between the micro light-emitting diode chip 230 and the redistribution layers 220-1 and 220-2.

Next, as shown in FIG. 6G, a film pasting, coating or molding process is performed to form a flexible material layer 250 covering the micro light-emitting diode chip 230 and the redistribution layers 220-1 and 220-2. In some embodiments, the flexible material layer 250 further covers the insulating layer 212, the first hard mask pattern 210 and the adhesive layer 204, and surrounds the edge 210E of the first hard mask pattern 210.

Next, as shown in FIG. 6H, an attaching process may be performed to attach the second carrier 260 to the flexible material layer 250 by a film-pasting machine. In some embodiments, the second carrier 260 has an adhesive layer 264, and the flexible material layer 250 is in contact with the adhesive layer 264. In some embodiments, the first carrier 200 and the second carrier 260 include the same or similar materials. The adhesive layer 264 includes polymer materials having adhesive force and easily to be dissociated and destroyed at the interface with the second carrier 260 in the subsequent removal process (such as, laser lift-off (LLO)), for example, UV tape, polyimide (PI), epoxy or silicone. Next, a removal process is performed to remove the first carrier 200 to expose the adhesive layer 204. In some embodiments, the removal process of the first carrier 200 includes laser debonding or other suitable removal processes.

Next, as shown in FIG. 6I, another removal process is performed to remove the adhesive layer 204, so that the bottom surface 210B of the first hard mask pattern 210, the bottom surfaces 206PB1 and 206P2B of the bonding pads 206P1 and 206P2, and the bottom surface of a portion of the flexible material 250 not covered by the first hard mask pattern 210 and the bonding pads 206P1 and 206P2 are exposed. In some embodiments, the removal process of the adhesive layer 204 includes chemical etching, plasma etching or other suitable removal processes.

Next, as shown in FIG. 6J, an anisotropic etching process (the dicing process) 400 is performed to remove the portion of the flexible material layer 250 at the periphery which is not covered by the first hard mask pattern 210 and the bonding pads 206P1 and 206P2 until the adhesive layer 264 is exposed to form the flexible material layer 250P. In some embodiments, the anisotropic etching process includes a dry etching process such as plasma etching, and oxygen may be used as an etchant for the plasma etching. During the plasma etching process using oxygen as an etchant, an anisotropic etching process may be performed on the flexible material layer 250 using the first hard mask pattern 210 (and the bonding pads 206P1, 206P2) as an etching mask due to the high etching selectivity (between 1:10 and 1:1000) between the first hard mask pattern 210 and the flexible material layer 250. After the anisotropic etching process, the edge 210E of the first hard mask pattern 210 is flush with the edge 250E of the flexible material layer 250P in the cross-sectional view shown in FIG. 6J.

Finally, a removal process is performed to remove the second carrier 260 and the adhesive layer 264 from the flexible material layer 250P to form the micro light-emitting diode pixel structure 500A as shown in FIG. 2A. In some embodiments, the first carrier 200 and the second carrier 260 are removed using the same or similar removal process, and the adhesive layers 204 and 264 are removed using the same or similar removal process.

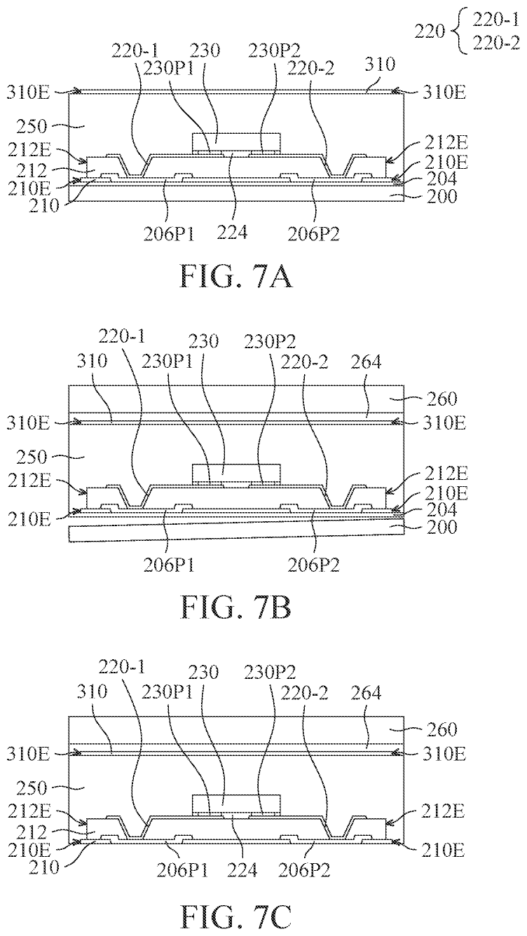

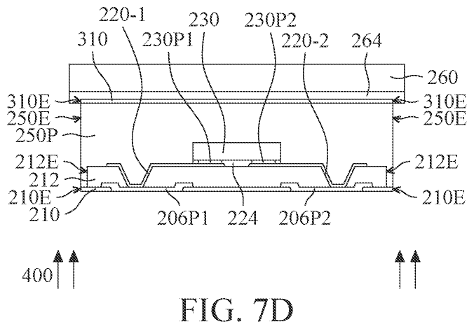

FIGS. 7A, 7B, 7C and 7D are schematic cross-sectional views at different stages of forming the micro light-emitting diode pixel structure 500B in accordance with some embodiments of the disclosure as shown in FIG. 2B, and the reference numbers the same or similar as those previously described with reference to FIGS. 1, 2A-2C, 3, 4, 5A-5C and 6A-6J denote the same or similar element.

In some embodiments, after performing the processes shown in FIGS. 6A to 6G in sequence, the second hard mask pattern 310 is formed on the flexible material layer 250 by the deposition and patterning processes, as shown in FIG. 7A. In some embodiments, the second hard mask pattern 310 covers a portion of the flexible material layer 250. In this embodiment, the edge 310E of the second hard mask pattern 310 may be flush with the edge 210E of the first hard mask pattern 210.

Next, as shown in FIG. 7B, the processes similar to those shown in FIG. 6H are performed to attach the second carrier 260 to the second hard mask pattern 310 and the flexible material layer 250. In some embodiments, the adhesive layer 264 is in contact with both the second hard mask pattern 310 and the flexible material layer 250. Afterwards, the first carrier 200 is removed to expose the adhesive layer 204.

Next, as shown in FIGS. 7C and 7D, the processes similar to those shown in FIGS. 61 and 6J are sequentially performed to remove the adhesive layer 204, and then the anisotropic etching process (the dicing process) 400 is performed to remove a portion of the flexible material layer 250 at the periphery which is not covered by the first hard mask pattern 210 until the adhesive layer 264 is exposed, so as to form the flexible material layer 250P. After performing the anisotropic etching process, the edge 250E of the flexible material layer 250P is flush with the edge 210E of the first hard mask pattern 210 and the edge 310E of the second hard mask pattern 310 in the cross-sectional view shown in FIG. 7D.

Finally, a removal process is performed to remove the second carrier 260 and the adhesive layer 264 from the second hard mask pattern 310 to form the micro light-emitting diode pixel structure 500B as shown in FIG. 2B.

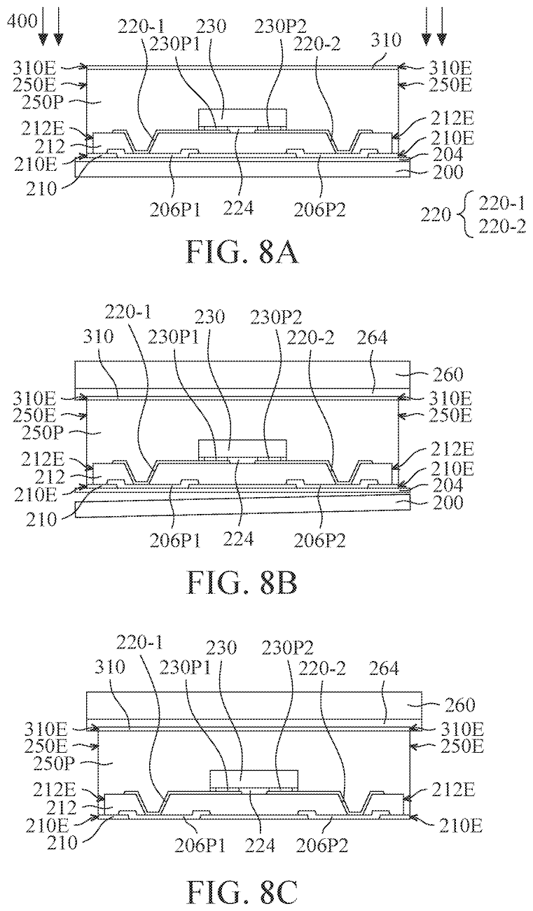

In some embodiments, the anisotropic etching process may be performed from the side of the flexible material layer away from the bonding pads. FIGS. 8A, 8B and 8C are schematic cross-sectional views at different stages of forming the micro light-emitting diode pixel structure 500B in accordance with some embodiments of the disclosure as shown in FIG. 2B, and the reference numbers the same or similar as those previously described with reference to FIGS. 1, 2A-2C, 3, 4, 5A-5C, 6A-6J and 7A-7D denote the same or similar element.

As shown in FIG. 8A, after performing the processes shown in FIGS. 6A-6G and 7A in sequence, the anisotropic etching process (the dicing process) 400 is performed to remove a portion of the flexible material layer 250 at the periphery which is not covered by the second hard mask pattern 310 until the adhesive layer 204 is exposed, so as to form the flexible material layer 250P. After performing the anisotropic etching process, the edge 250E of the flexible material layer 250P is flush with the edge 310E of the second hard mask pattern 310 and the edge 210E of the first hard mask pattern 210 in the cross-sectional view shown in FIG. 8A.

Next, as shown in FIGS. 8B and 8C, the processes similar to those shown in FIGS. 7B and 7C are performed to attach the second carrier 260 to the second hard mask pattern 310, and then remove the first carrier 200 and adhesive layer 204.

Finally, a removal process is performed to remove the second carrier 260 and the adhesive layer 264 from the second hard mask pattern 310 to form the micro light-emitting diode pixel structure 500B as shown in FIG. 2B.

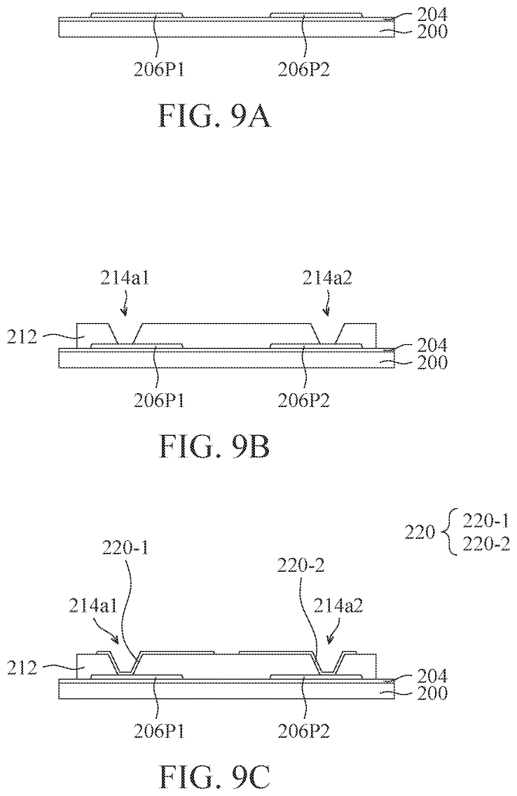

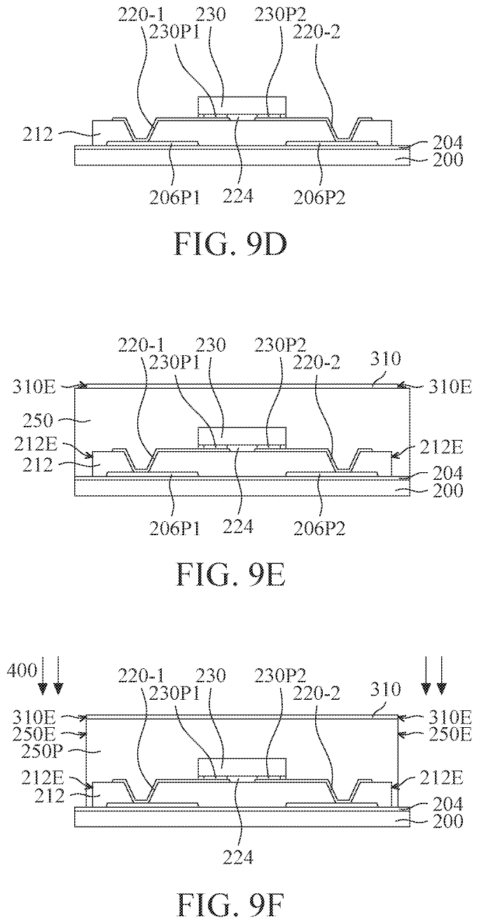

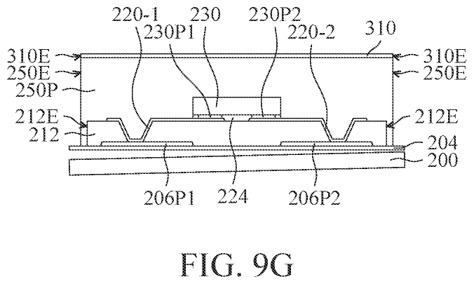

FIGS. 9A, 9B, 9C, 9D, 9E, 9F and 9G are schematic cross-sectional views at different stages of forming the micro light-emitting diode pixel structure 500C in accordance with some embodiments of the disclosure as shown in FIG. 2C, and the reference numbers the same or similar as those previously described with reference to FIGS. 1, 2A-2C, 3, 4, 5A-5C, 6A-6J, 7A-7D and 8A-8C denote the same or similar element.

As shown in FIG. 9A, after performing the processes shown in FIG. 6A in sequence, a plating process and a subsequent patterning process are performed to form the bonding pads 206P1 and 206P2 on the first carrier 200. In addition, the bonding pads 206P1 and 206P2 are in contact with the adhesive layer 204.

Next, as shown in FIG. 9B, the processes similar to those shown in FIG. 6D are performed to form the insulating layer 212 on the adhesive layer 204 and the bonding pads 206P1 and 206P2. The insulation layer 212 may have the via holes 214a1 and 214a2 to expose the bonding pads 206P1 and 206P2.

Next, as shown in FIG. 9C, the processes similar to those shown in FIG. 6E are performed to form the redistribution layers 220-1 and 220-2 on the insulating layer 212. The redistribution layers 220-1 and 220-2 may cover a portion of the insulation layers 212. Moreover, the redistribution layers 220-1 and 220-2 are electrically connected to the corresponding bonding pads 206P1 and 206P2 through the via holes 214a1 and 214a2.

Next, as shown in FIG. 9D, the processes similar to those shown in FIG. 6F are performed to transfer the micro light-emitting diode chip 230 onto the first carrier 200, so that the micro light-emitting diode chip 230 are electrically connected to the corresponding redistribution layers 220-1 and 220-2.

Next, as shown in FIG. 9E, the processes similar to those shown in FIG. 6G and FIG. 7A in sequence are performed to form the flexible material layer 250 covering the micro light-emitting diode chip 230 and the redistribution layers 220-1 and 220-2, and then, the second hard mask pattern 310 is formed on the flexible material layer 250. In some embodiments, the edge 212E of the insulating layer 212 may be located inward relatively to the edge 310E of the second hard mask pattern 310. Alternatively, the edge 212E of the insulating layer 212 may be not located inward relatively to the edge 310E of the second hard mask pattern 310, and may be connected with the insulating layer 212 of the intermediate structure of the adjacent micro light-emitting diode pixel structure.

Next, as shown in FIG. 9F, the processes similar to those shown in FIG. 8A are performed. The anisotropic etching process 400 is performed to remove a portion of the flexible material layer 250 at the periphery which is not covered by the second hard mask pattern 310 to form the flexible material layer 250P. After performing the anisotropic etching process, the edge 310E of the second hard mask pattern 310 is flush with the edge 250E of the flexible material layer 250P in the cross-sectional view shown in FIG. 9F.

Next, as shown in FIG. 9G, a removal process is performed to remove the first carrier 200 to expose the adhesive layer 204.

Finally, another removal process is performed to remove the adhesive layer 204 and thereby forming the micro light-emitting diode pixel structure 500C shown in FIG. 2C.

In some embodiments, the method of forming the micro light-emitting diode pixel structures 500D and 500E shown in FIGS. 5A and 5B are similar to that of forming the micro light-emitting diode pixel structures 500A and 500B shown in FIGS. 2A and 2B, which are shown in FIGS. 6A-6J, 7A-7D, and 8A-8C. The differences are described below. For example, after performing the processes similar to those shown in FIGS. 6A-6C to form the bonding pads 206P1 and 206P2, the adhesive layer 304 may be coated on the first hard mask pattern 210 between the bonding pads 206P1 and 206P2. Next, the control device 340 is disposed on the first carrier 200 by transfer processes such as stamp transferring or laser transferring so that the bonding pads 206P1 and 206P2 are located at a side of the control device 340 opposite to the contact pads 340P1 and 340P3 of the control device 340. In addition, after performing the processes similar to those shown in FIG. 6D to form the insulating layer 212, the control device 340 is also covered by the insulating layer 212 and the contact pads 340P1 and 340P3 of the control device 340 are exposed from the insulating layer 212. Furthermore, after performing the processes similar to those shown in FIGS. 6E and 6F, the redistribution layers 320-1, 320-2 and 320-3 are formed on the insulating layer 212, so that the control device 340 is electrically connected to the micro light-emitting diode chip 330 by the redistribution layers 320. The processes similar to those shown in FIGS. 6F to 6J are sequentially performed to form the micro light-emitting diode pixel structure 500D. Alternatively, the processes similar to those shown in FIGS. 6F, 6G, and 7A-7D (or FIGS. 6F, 6G, 7A, and 8A-8C) are sequentially performed to form the micro light-emitting diode pixel structure 500E.

In some embodiments, the method of forming the micro light-emitting diode pixel structure 500F shown in FIG. 5C is similar to that of forming the micro light-emitting diode pixel structure 500C shown in FIGS. 2C, which is shown in FIGS. 9A-9G. The differences are described below. For example, after performing the processes similar to those shown in FIG. 9A, the adhesive layer 304 may be coated on the adhesive layer 204 between the bonding pads 206P1 and 206P2. Next, the control device 340 is disposed on the adhesive layer 304 by transfer processes such as stamp transferring and laser transferring so that the bonding pads 206P1 and 206P2 are located on a side of the control device 340 opposite to the contact pads 340P1 and 340P3 of the control device 340. In other embodiments, the control device 340 may be disposed on the first carrier 200 between the bonding pads 206P1 and 206P2 by the adhesive layer 204 without using the coated adhesive layer 304. In addition, after performing the processes similar to those shown in FIG. 9B to form the insulating layer 212, the control device 340 is also covered by the insulating layer 212 and the contact pads 340P1 and 340P3 of the control device 340 are exposed from the insulating layer 212. Furthermore, after performing the processes similar to those shown in FIGS. 9C and 9D, the redistribution layers 320-1, 320-2 and 320-3 are formed on the insulating layer 212, so that the control device 340 is electrically connected to the micro light-emitting diode chip 330 by the redistribution layers 320. The processes similar to those shown in FIGS. 9E to 9G is sequentially performed to form the micro light-emitting diode pixel structure 500F.

Embodiments of the disclosure provide a micro light-emitting diode pixel structure and a method for forming the same. Compared with the singulation process (such as laser cutting, dicing saw cutting, or other conventional dicing process) of the conventional light-emitting diode pixel structure, the micro light-emitting diode pixel structure in accordance with some embodiments of the disclosure has a hard mask pattern serving as the bottommost and/or topmost layer of the pixel structure and as an etching mask. Therefore, the anisotropic etching process such as plasma etching may be performed from the bottom and/or top surface of the pixel structure for singulation. Because of the high etching selectivity between the hard mask pattern and the flexible material layer, the top-view shape and dimension of the micro light-emitting diode pixel structure may be formed with better precision/accuracy and without destroying the sidewall profile of the micro light-emitting diode pixel structure. Therefore, the process yield of micro light-emitting diode pixel structure can be improved.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A micro light-emitting diode pixel structure, comprising:
micro light-emitting diode chips arranged, wherein each of the micro light-emitting diode chips includes an electrode surface and a light-emitting surface;
redistribution layers arranged under the electrode surfaces of the micro light-emitting diode chips and electrically connected to the micro light-emitting diode chips respectively;
bonding pads disposed under the redistribution layers;
an insulating layer disposed between the redistribution layers and the bonding pads, wherein the redistribution layers pass through the insulating layer to electrically connect to the bonding pads;
a flexible material layer disposed on the insulating layer to cover the micro light-emitting diode chips, the redistribution layers and the insulating layer; and
a first hard mask pattern disposed under or above the flexible material layer;
wherein, in a cross-sectional view, the first hard mask pattern has a first edge and the flexible material layer has a second edge, and the first edge is flush with the second edge.

2. The micro light-emitting diode pixel structure as claimed in claim 1, wherein a bottom surface of the first hard mask pattern is flush with a bottom surface of each of the bonding pads.

3. The micro light-emitting diode pixel structure as claimed in claim 1, wherein a bottom surface of the first hard mask pattern and a bottom surface of each of the bonding pads collectively form a bottom surface of the micro light-emitting diode pixel structure.

4. The micro light-emitting diode pixel structure as claimed in claim 1, further comprising:
a second hard mask pattern disposed at a side of the flexible material layer opposite to the first hard mask pattern.

5. The micro light-emitting diode pixel structure as claimed in claim 1, wherein the insulating layer surrounds the bonding pads.

6. The micro light-emitting diode pixel structure as claimed in claim 1, wherein the insulating layer has a third edge located closer to the micro light-emitting diode chips than the first edge of the first hard mask pattern.

7. The micro light-emitting diode pixel structure as claimed in claim 1, wherein a material of the first hard mask pattern is different from a material of the insulating layer.

8. The micro light-emitting diode pixel structure as claimed in claim 1, wherein the first hard mask pattern comprises silicon dioxide.

9. The micro light-emitting diode pixel structure as claimed in claim 1, wherein an etching selectivity ratio of the first hard mask pattern to the flexible material layer is between 1:10 and 1:1000.

10. The micro light-emitting diode pixel structure as claimed in claim 1, further comprising:
a control device disposed between the micro light-emitting diode chips and the bonding pads, wherein the control device is electrically connected to the micro light-emitting diode chips.

11. The micro light-emitting diode pixel structure as claimed in claim 1, wherein a top-view shape of the micro light-emitting diode pixel structure comprises a polygon, a circle or an ellipse.

12. The micro light-emitting diode pixel structure as claimed in claim 1, wherein in a top view, the second edge of the flexible material layer is a concave-convex edge.

13. The micro light-emitting diode pixel structure as claimed in claim 1, wherein a vertical orthographic projection of the first hard mask pattern encompasses a vertical orthographic projection of the bonding pads.

14. A method for forming a micro light-emitting diode pixel structure, comprising:
providing a first carrier;
forming a first adhesive layer on a surface of the first carrier;
forming a first hard mask pattern on the first adhesive layer, wherein the first hard mask pattern has openings to expose the first adhesive layer;
forming bonding pads on the first hard mask pattern, wherein the bonding pads are in contact with the first adhesive layer through the openings;
forming an insulating layer on the first hard mask pattern and the bonding pads, wherein the insulating layer has via holes to expose the bonding pads;
forming redistribution layers on the insulating layer, wherein the redistribution layers are electrically connected to the bonding pads through the via holes;
providing micro light-emitting diode chips on the first carrier, wherein the micro light-emitting diode chips are electrically connected to the redistribution layers;
forming a flexible material layer on the first carrier to cover the micro light-emitting diode chips, the redistribution layers, and the insulating layer;
attaching a second carrier to the flexible material layer, wherein the second carrier has a second adhesive layer, and the flexible material layer is in contact with the second adhesive layer;
removing the first carrier and the first adhesive layer;
performing an anisotropic etching process to remove a portion of the flexible material layer at the periphery which is not overlapped with the first hard mask pattern in a vertical direction, wherein after performing the anisotropic etching process, in a cross-sectional view, the first hard mask pattern has a first edge and the flexible material layer has a second edge, and the first edge is flush with the second edge; and
removing the second carrier and the second adhesive layer.

15. The method for forming a micro light-emitting diode pixel structure as claimed in claim 14, further comprising:
forming a second hard mask pattern on the flexible material layer after forming the flexible material layer.

16. The method for forming a micro light-emitting diode pixel structure as claimed in claim 15, wherein an edge of the second hard mask pattern is flush with the first edge of the first hard mask pattern after performing the anisotropic etching process.

17. The method for forming a micro light-emitting diode pixel structure as claimed in claim 14, further comprising:
arranging a control device on the first carrier before forming the redistribution layers, wherein the control device is disposed between the micro light-emitting diode chips and the bonding pads, and wherein the control device is electrically connected to the micro light-emitting diode chips by the redistribution layers.

18. A method for forming a micro light-emitting diode pixel structure, comprising:
providing a carrier;
forming an adhesive layer on a surface of the carrier;
forming bonding pads on the adhesive layer;
forming an insulating layer on the adhesive layer and the bonding pads, wherein the insulating layer has via holes to expose the bonding pads;
forming redistribution layers on the insulating layer, wherein the redistribution layers are electrically connected to the bonding pads through the via holes;
providing micro light-emitting diode chips on the carrier, wherein the micro light-emitting diode chips are electrically connected to the redistribution layers;
forming a flexible material layer on the carrier to cover the micro light-emitting diode chips, the redistribution layers, and the insulating layer;
forming a hard mask pattern on the flexible material layer;
performing an anisotropic etching process to remove a portion of the flexible material layer at the periphery which is not overlapped with the hard mask pattern in a vertical direction, wherein after performing the anisotropic etching process, in a cross-sectional view, the hard mask pattern has a first edge and the flexible material layer has a second edge, and the first edge is flush with the second edge; and
removing the carrier and the adhesive layer.

19. The method for forming a micro light-emitting diode pixel structure as claimed in claim 18, further comprising:
arranging a control device on the carrier before forming the redistribution layers, wherein the control device is disposed between the micro light-emitting diode chips and the bonding pads, and wherein the control device is electrically connected to the micro light-emitting diode chips by the redistribution layers.

20. The method for forming a micro light-emitting diode pixel structure as claimed in claim 18, wherein the insulating layer has a third edge and the third edge is closer to the micro light-emitting diode chips than the first edge of the hard mask pattern.
